(19) United States
(12) Patent Application Publication
(10) Pub. No.: US 2016/0126336 A1
(43) Pub. Date: May 5, 2016

(54) METHOD OF IMPROVED CA/CB CONTACT AND DEVICE THEREOF

(71) Applicant: GLOBALFOUNDRIES Inc., Grand Cayman (KY)

(72) Inventors: Xusheng WU, Ballston Lake, NY (US); Changyong XIAO, Mechanicville, NY (US); Min-hwa CHI, Malta, NY (US)

(21) Appl. No.: 14/527,250

(22) Filed: Oct. 29, 2014

(51) Int. Cl. H01L 29/66; H01L 29/49; H01L 29/423; H01L 21/311; H01L 29/417

(52) U.S. Cl. CPC H01L 29/66515; H01L 29/66545; H01L 21/31116; H01L 29/41775; H01L 29/42356; H01L 29/4958; H01L 29/6653

(57) ABSTRACT

Processes for forming merged CA/CB constructs and the resulting devices are disclosed. Embodiments include providing a replacement metal gate (RMG) between first and second sidewall spacers surrounded by an insulator on a substrate, the RMG having a dielectric layer directly on the first and second sidewall spacers and having metal on the dielectric layer; providing an oxide layer over the insulator, the first and second sidewall spacers, and the RMG; forming a source/drain contact hole through the oxide layer and the insulator, adjacent to the first sidewall spacer; forming a gate contact hole through the oxide layer over the source/drain contact hole and extending to the metal of the RMG; enlarging the source/drain contact hole to the metal of the RMG; and filling the enlarged source/drain contact hole and gate contact hole with metal.

### TECHNICAL FIELD

The present disclosure relates to process flows for contact formation. More particularly, the present disclosure relates to gate contacts for replacement metal gate (RMG) processing.

### BACKGROUND

Although in many structures, source/drain contacts (CA) and gate contacts (CB) are separated, in some circuits, the gate and source/drain need to be connected, thereby requiring a merged CA/CB contact. FIG. 1 illustrates a conventional merged CA/CB contact. As shown, a RMG 101, surrounded by spacers 103, is formed in insulator 105 on substrate 107. RMG 101 includes high-k (HK) dielectric layer 109, work function metal 111, and gate metal fill 113. Middle-of-line (MOL) oxide layers 115 are formed on RMG 101 and insulator 105. CA 117 and CB 119 are formed through insulator 105 and oxide layers 115. However, as illustrated at 121, there are spacer and HK materials on the sidewall of the gate within the CA/CB contact. Thus, instead of a single merged contact or construct, CA/CB contacts are separated into two contacts, CA 117 and CB 119. Within such a design, the quality of such contacts is process-dependent particularly because the contact area is mainly at the upper portion of gate 101, and spacer 103 and HK dielectric 109 are not utilized for conducting. In addition, any misalignment in the CA/CB contact patterning significantly reduces the process margin and results in openings that taper sharply and are difficult to fill. As a result, overall device yield is reduced.

A need therefore exists for methodology enabling formation of a CA/CB construct with an increased gate contact area and the resulting device.

### SUMMARY

An aspect of the present disclosure is a merged CA/CB construct contacting one side of a RMG.

Another aspect of the present disclosure is a merged CA/CB construct contacting both sides of a RMG.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: providing a replacement metal gate (RMG) between first and second sidewall spacers surrounded by an insulator on a substrate, the RMG having a dielectric layer directly on the first and second sidewall spacers and having metal on the dielectric layer; providing an oxide layer over the insulator, the first and second sidewall spacers, and the RMG; forming a source/drain contact hole through the oxide layer and the insulator, adjacent to the first sidewall spacer; forming a gate contact hole through the oxide layer over the source/drain contact hole and extending to the metal of the RMG; enlarging the source/drain contact hole to the metal of the RMG; and filling the enlarged source/drain contact hole and gate contact hole with metal.

Aspects of the present disclosure include the enlarging of the source/drain contact hole including: removing the insulator between the source/drain contact hole and the first sidewall spacer; and removing the first sidewall spacer and the dielectric layer on the first sidewall spacer. Further aspects include removing the insulator between the source/drain contact hole and the first sidewall spacer concurrently with forming the gate contact hole. Other aspects include removing the insulator between the source/drain contact hole and the first sidewall spacer and forming the gate contact hole by reactive ion etching (RIE). Another aspect includes removing the first sidewall spacer and dielectric layer by a second RIE. Additional aspects include the dielectric layer including a high-K (HK) dielectric. Further aspects include the metal of the RMG including at least one work function metal directly on the dielectric layer and tungsten filling a remainder of the RMG, the method further including removing the at least one work function metal on a first sidewall spacer side of the tungsten concurrently with the first sidewall spacer and the dielectric layer. Additional aspects include forming the gate contact hole extending over a portion of the insulator surrounding the second sidewall spacer; removing the portion of the insulator under the gate contact hole and surrounding the second sidewall spacer concurrently with forming the gate contact hole; and removing the second sidewall spacer, the dielectric layer on the second sidewall spacer, and the at least one work function metal on both sides of the tungsten concurrently with the first sidewall spacer and the dielectric layer on the first sidewall spacer.

Another aspect of the present disclosure is a device including: a replacement metal gate having a metal; and a source/drain and gate contact construct including: a first portion directly contacting a sidewall of the metal, and a second portion over the first portion and the metal.

Aspects include the metal including at least one work function metal on opposite sides of a metal fill, and the first portion directly contacting the at least one work function metal. Further aspects include the metal including tungsten, and the first portion directly contacting the tungsten. Additional aspects include the source/drain and gate contact construct including a third portion directly contacting a second sidewall of the tungsten; and the second portion extending over the third portion. Other aspects include the source/drain and gate contact construct including tungsten.

Another aspect of the present disclosure is a method including: providing a replacement metal gate (RMG) between first and second sidewall spacers surrounded by an insulator on a substrate, the RMG having first and second portions of a dielectric layer directly on the first and second sidewall spacers, respectively, and having metal filling a space between the first and second portions of the dielectric layer; providing an oxide layer over the insulator, the first and second sidewall spacers, and the RMG; forming a source/drain contact hole through the oxide layer and the insulator, adjacent to the first sidewall spacer; performing a first reactive ion etch (RIE) to form a gate contact hole through the oxide layer over the source/drain contact hole and extending to the metal of the RMG; enlarging the source/drain contact hole to the first sidewall spacer concurrently with forming the gate contact hole; performing a second RIE to remove the first sidewall spacer and first portion of the dielectric layer to expose the metal, further enlarging the source/drain contact hole; and filling the further enlarged source/drain contact hole and gate contact hole with a contact metal.

Aspects include the dielectric layer including a high-K (HK) dielectric. Further aspects include the metal of the RMG including at least one work function metal directly on the first portion of the dielectric layer and tungsten filling a remainder of the RMG, and the second RIE exposing the at least one work function metal. Further aspects include the metal of the RMG including at least one work function metal directly on each of the first and second portions of the dielectric layer and tungsten filling a remainder of the RMG, the method further including removing the at least one work function metal on the first portion of the dielectric layer concurrently with the first sidewall spacer and the first portion of the dielectric layer. Additional aspects include forming the gate contact hole extending over the insulator surrounding the second sidewall spacer; removing the insulator under the gate contact hole and surrounding the second sidewall spacer concurrently with forming the gate contact hole; and removing the second sidewall spacer, the second portion of the dielectric layer, and the at least one work function metal on the second portion of the dielectric layer concurrently with the first sidewall spacer and the first portion of the dielectric layer. Further aspects include forming the source/drain contact down to a source/drain region, and forming a silicide on the source/drain region prior to filling the enlarged source/drain contact hole. Another aspect includes the contact metal including tungsten.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 schematically illustrates a conventional CA/CB construct;

FIGS. 2A through 2E schematically illustrate a process flow for a small CA/CB construct, in accordance with an exemplary embodiment;

FIGS. 3A through 3B schematically illustrate an alternative process flow for FIGS. 2D through 2E, in accordance with an exemplary embodiment;

FIGS. 4A through 4E schematically illustrate a process flow for a large CA/CB contact, in accordance with an exemplary embodiment; and

FIGS. 5A through 5B schematically illustrate an alternative process flow for FIGS. 4D through 4E, in accordance with an exemplary embodiment.

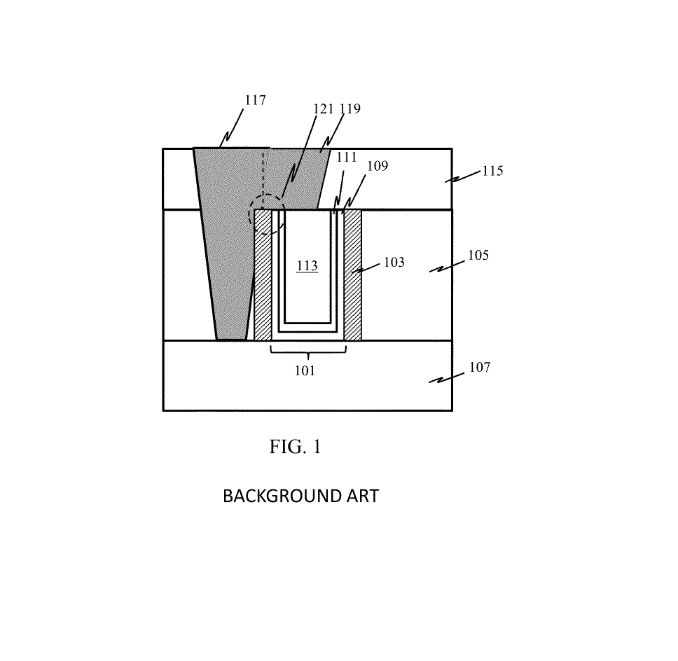

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of low process margin and unreliable contact formation attendant upon forming conventional CA/CB contacts. In accordance with embodiments of the present disclosure, a merged CA/CB construct includes an upper portion along an upper surface of the gate and a lower portion in contact with at least one vertical surface of either a work function metal or the metal fill of the gate.

Methodology in accordance with embodiments of the present disclosure includes providing a replacement metal gate (RMG) between first and second sidewall spacers surrounded by an insulator on a substrate, the RMG having a dielectric layer directly on the first and second sidewall spacers and having metal on the dielectric layer. An oxide layer is provided over the insulator, the first and second sidewall spacers, and the RMG. A source/drain contact hole through the oxide layer and the insulator, is formed adjacent to the first sidewall spacer, and a gate contact hole is formed through the oxide layer over the source/drain contact hole extending to the metal of the RMG. The source/drain contact hole is extended to the metal of the RMG, and the enlarged source/drain contact hole and gate contact hole is filled with metal.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

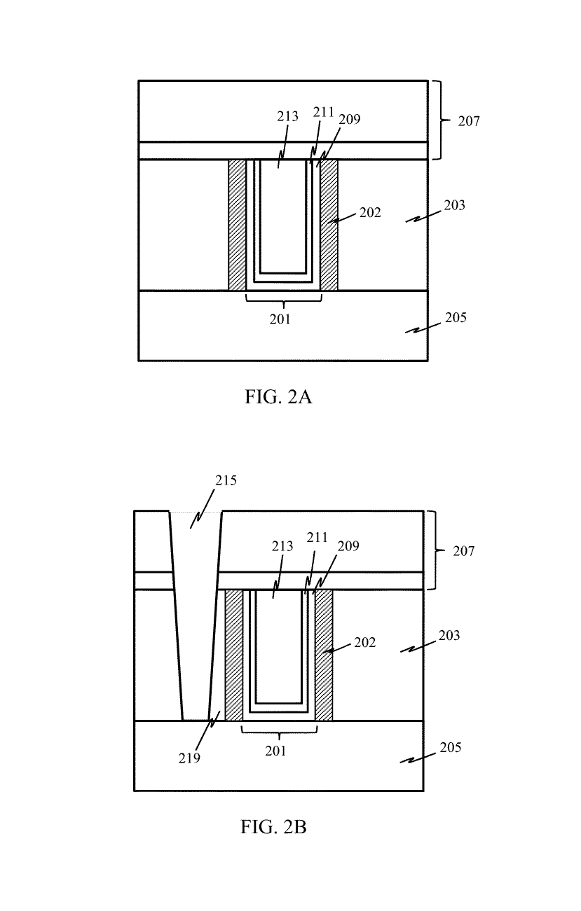

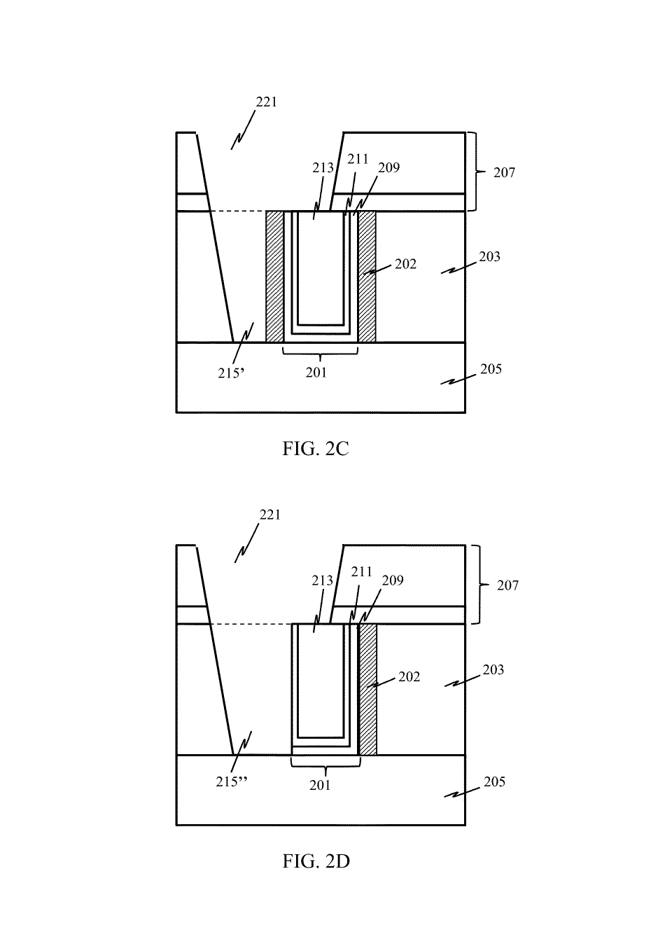

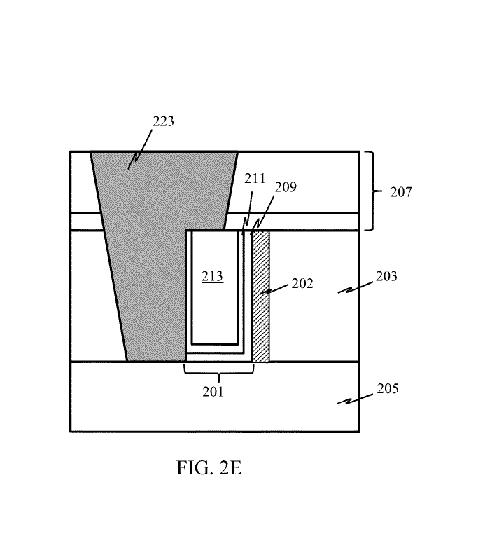

FIGS. 2A through 2E schematically illustrate a process flow for a small CA/CB construct, in accordance with an exemplary embodiment of the present disclosure. FIG. 2A illustrates RMG 201, between spacers 202, formed in insulator 203 on substrate 205. Middle-of-line (MOL) oxide layers 207 are formed on RMG 201 and insulator 203. As shown, RMG 201 includes HK dielectric layer 209, work function metal 211, and gate metal fill 213, e.g. tungsten.

Adverting to FIG. 2B, an opening 215, corresponding to a source/drain contact, i.e. CA, is formed through oxide layers 207 and insulator 203 down to upper surface 217 of substrate 205. As shown, opening 215 is formed on one side of RMG 201. As further shown, a portion 219 of insulator 203 lies between opening 215 and spacer 202.

As shown in FIG. 2C, another opening 221, corresponding to a gate contact, i.e. CB, is formed through oxide layers 207 down to an upper surface of RMG 201. Concurrently, the opening 215 is expanded to opening 215′ by removing the insulator 219 between opening 215 and spacer 202. Both the formation of opening 221 and the expansion of opening 215 are performed by etching, e.g. by RIE.

Adverting to FIG. 2D, spacer 202 and the portion of HK dielectric layer 209 on the side of first opening 215′ are removed, forming opening 215″. For example, the spacer and HK dielectric layer may be removed by RIE.

As illustrated in FIG. 2E, openings 215″ and 221 are filled with a contact metal, forming CA/CB construct 223. The contact metal may, for example, include tungsten (W). Prior to filling the openings, a silicide step (not shown for illustrative convenience) may be performed. For example, a titanium nitride (TiN) fill and silicidation step may be performed before the contact fill.

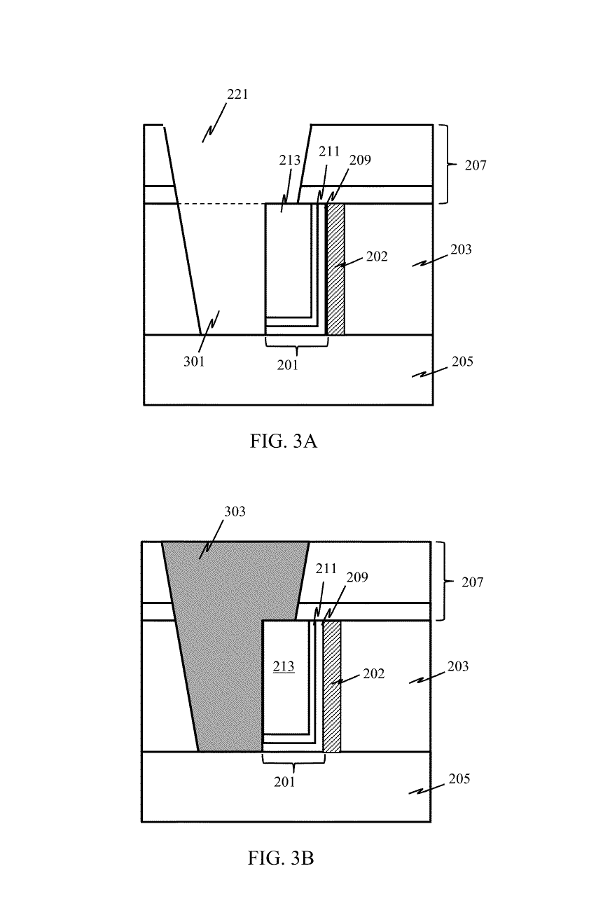

Adverting to FIGS. 3A and 3B, a CA/CB construct may be formed to contact a vertical sidewall of gate metal fill 213 for gate 201. For example, as illustrated in FIG. 3A, after opening 221 is formed, spacer 202, the portion of HK dielectric layer 209 on the side of first opening 215′, and the portion of work function metal 211 on the side of the first opening 215′ are removed, forming opening 301. For example, the spacer, HK dielectric layer, and work function metal may be removed by RIE.

As illustrated in FIG. 3B, openings 301 and 221 are filled with a contact metal, forming CA/CB construct 303. The contact metal may, for example, include tungsten (W). Prior to filling the openings, a silicide step (not shown for illustrative convenience) may be performed. For example, a titanium nitride (TiN) fill and silicidation step may be performed before the contact fill.

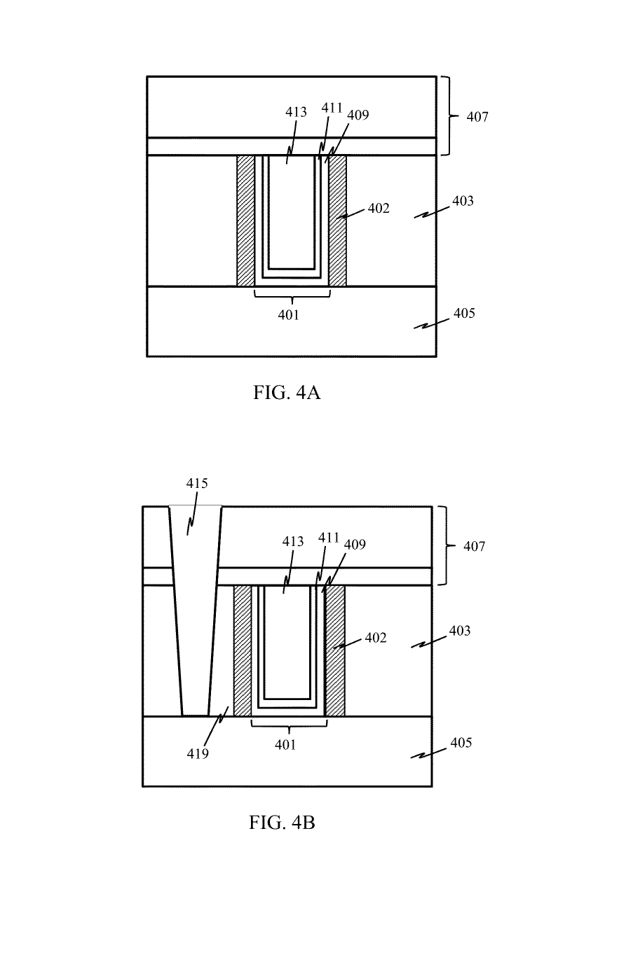

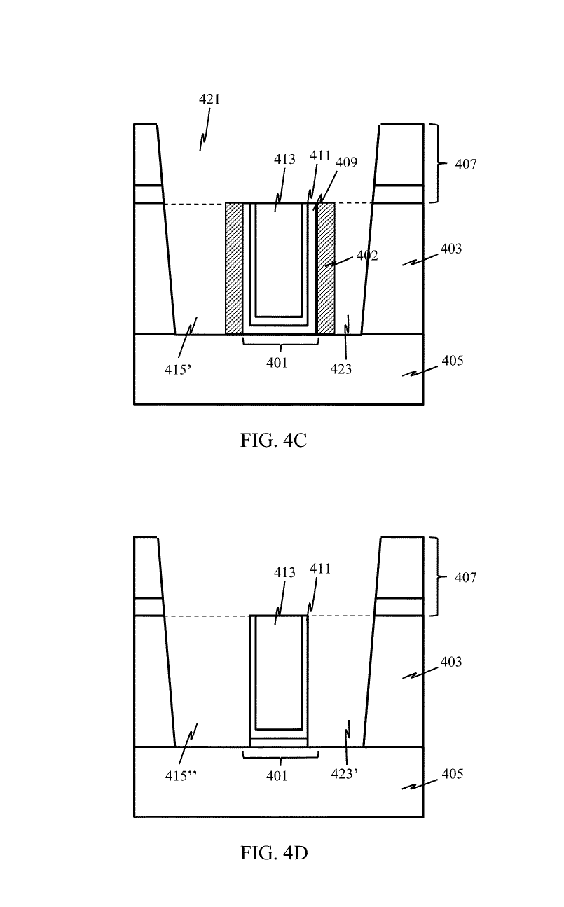

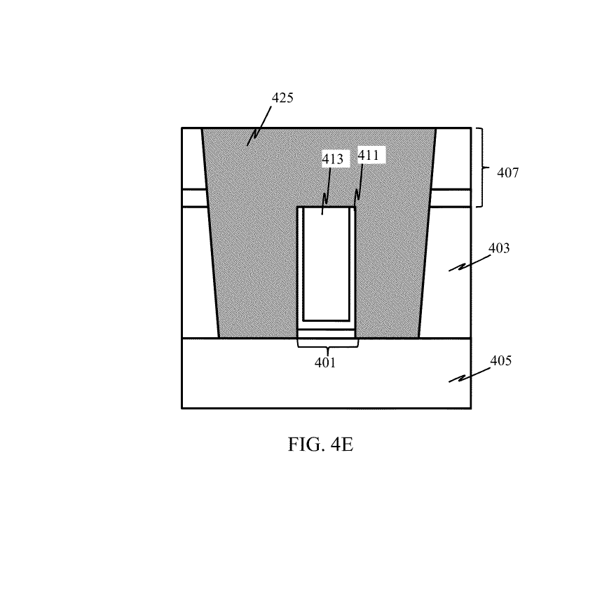

FIGS. 4A through 4E schematically illustrate a process flow for a large CA/CB contact, in accordance with an exemplary embodiment of the present disclosure. FIG. 4A illustrates RMG 401 formed between spacers 402, in insulator 403, on substrate 405. MOL oxide layers 407 are formed on RMG 401 and insulator 403. As shown, RMG 401 includes HK dielectric layer 409, work function metal 411, and gate metal fill 413, for example tungsten. Adverting to FIG. 4B, an opening 415, corresponding to a source/drain contact, i.e. CA, is formed through oxide layers 407 and insulator 403 down to upper surface 417 of substrate 405. As shown, first opening 415 is formed on one side of RMG 401. As further shown, a portion 419 of insulator 403 lies between first opening 415 and spacer 402.

Adverting to FIG. 4C, another opening 421, corresponding to a gate contact, i.e. CB, is formed through oxide layers 407 down to an upper surface of RMG 401. Concurrently, the opening 415 is expanded to opening 415′ by removing the insulator 419 between opening 415 and spacer 402, and a portion of insulator 403 adjacent spacer 402 on the opposite side of RMG 401 is also removed forming opening 423. The formation of openings 421 and 423 and the expansion of opening 415 are performed by etching, e.g. by RIE.

Adverting to FIG. 4D, spacers 402 and dielectric layer 409 are removed on both sides of RMG 401, forming openings 415″ and 423′. For example, the spacer and HK dielectric layer may be removed by RIE.

Adverting to FIG. 4E, openings 415″, 421, and 423′ are filled with contact metal, forming CA/CB construct 425. The contact metal may, for example, include tungsten (W). Prior to filling the openings, a silicide step (not shown for illustrative convenience) may be performed. For example, a titanium nitride (TiN) fill and silicidation step may be performed before the contact fill. As shown, CA/CB construct 425 will cover both sides of RMG 401 with an enlarged contact area.

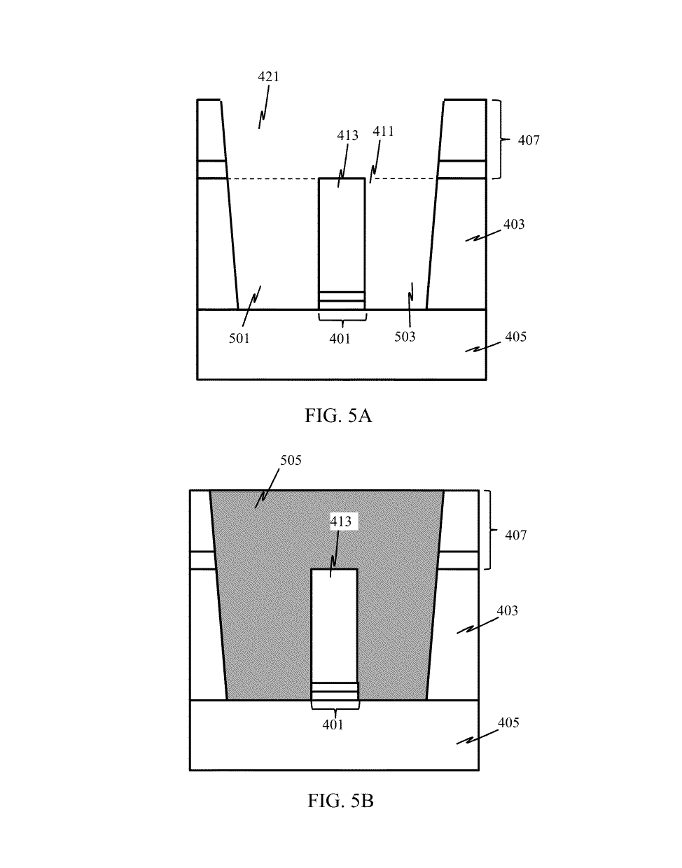

Adverting to FIGS. 5A and 5D, a CA/CB construct may be formed to contact the vertical sidewalls of gate metal fill 413 for gate 401. For example, as illustrated in FIG. 5A, after openings 421 and 423 are formed, spacers 402, the portions of HK dielectric layer 409, and of work function metal 411 on both sides of RMG 401 are removed, forming openings 501 and 503, respectively. For example, the spacers, HK dielectric layer, and work function metal may be removed by RIE.

As illustrated in FIG. 5B, openings 501, 503, and 421 are filled with a contact metal, forming CA/CB construct 505. The contact metal may, for example, include tungsten (W). Prior to filling the openings, a silicide step (not shown for illustrative convenience) may be performed. For example, a titanium nitride (TiN) fill and silicidation step may be performed before the contact fill.

The embodiments of the present disclosure can achieve several technical effects, including an increased contact area, which is especially beneficial for FinFETs and which reduces contact resistance, an increased misalignment process margin by 20 to 30 nm, more reliable tungsten filling, due to a smaller aspect ratio, and improved open/short yield, all of which contribute to higher yield and improved device performance (e.g., a smaller RC time constant). The present disclosure enjoys industrial applicability associated with the designing and manufacturing of any of various types of highly integrated semiconductor devices used in microprocessors, smart phones, mobile phones, cellular handsets, set-top boxes, DVD recorders and players, automotive navigation, printers and peripherals, networking and telecom equipment, gaming systems, and digital cameras, particularly for 14 nm technology nodes and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
providing a replacement metal gate (RMG) between first and second sidewall spacers, the RMG and the first and second sidewall spacers surrounded by an insulator on a substrate, wherein the RMG comprises a dielectric layer having an inner side and an outer side, and a metal layer and the outer side of the dielectric layer directly abuts the first and second sidewall spacers and the metal layer directly contacts the inner side of the dielectric layer;
providing an oxide layer over the insulator, the first and second sidewall spacers, and the RMG;
forming a source/drain contact hole through the oxide layer and the insulator, adjacent to, but not contacting, the first sidewall spacer, leaving a sliver portion of the insulator between the source/drain contact hole and the first sidewall spacer;
forming a gate contact hole through the oxide layer over the source/drain contact hole and extending to the metal layer at an upper surface of the RMG, while concurrently removing the sliver portion of the insulator;
enlarging the source/drain contact hole to the metal layer of the RMG by removing the first sidewall spacer and a portion of the dielectric layer between the first sidewall spacer and the metal layer; and
filling the enlarged source/drain contact hole and gate contact hole with a contact metal.

2.-3. (canceled)

4. The method according to claim 1, comprising removing the sliver portion of the insulator between the source/drain contact hole and the first sidewall spacer and forming the gate contact hole by reactive ion etching (RIE).

5. The method according to claim 4, comprising removing the first sidewall spacer and the portion of the dielectric layer by a second RIE.

6. The method according to claim 5, wherein the dielectric layer comprises a high-K (HK) dielectric.

7. The method according to claim 1, wherein the metal layer of the RMG includes at least one work function metal and a remainder of the RMG is filled with tungsten, the method further comprising removing the at least one work function metal on a first sidewall spacer side of the tungsten concurrently with the first sidewall spacer and the dielectric layer.

8. The method according to claim 7, further comprising:
forming the gate contact hole extending over a portion of the insulator surrounding the second sidewall spacer;
removing the portion of the insulator under the gate contact hole and surrounding the second sidewall spacer concurrently with forming the gate contact hole; and
removing the second sidewall spacer, the dielectric layer on the second sidewall spacer, and the at least one work function metal on both sides of the tungsten concurrently with the first sidewall spacer and the dielectric layer on the first sidewall spacer.

9. A device comprising:
a replacement metal gate having a metal; and
a source/drain and gate contact construct comprising:
a first portion directly contacting a sidewall of the metal, and
a second portion over the first portion and the metal.

10. The device according to claim 9, wherein metal includes at least one work function metal on opposite sides of a metal fill, and the first portion directly contacts the at least one work function metal.

11. The device according to claim 9, wherein the metal includes tungsten, and the first portion directly contacts the tungsten.

12. The device according to claim 11, wherein
the source/drain and gate contact construct comprises a third portion directly contacting a second sidewall of the tungsten; and
the second portion extends over the third portion.

13. (canceled)

14. A method comprising:
providing a replacement metal gate (RMG) between first and second sidewall spacers, the RMG and the first and second sidewall spacers surrounded by an insulator on a substrate, wherein the RMG comprises first and second portions of a dielectric layer directly contacting the first and second sidewall spacers, respectively, and metal filling a space between the first and second portions of the dielectric layer;
providing an oxide layer over the insulator, the first and second sidewall spacers, and the RMG;
forming a source/drain contact hole through the oxide layer and the insulator, adjacent to, but not contacting, the first sidewall spacer, leaving a sliver portion of the insulator between the source/drain contact hole and the first sidewall spacer;
performing a first reactive ion etch (RIE) to form a gate contact hole through the oxide layer over the source/drain contact hole and extending to the metal at an upper surface of the RMG, while concurrently removing the sliver portion of the insulator;
enlarging the source/drain contact hole to the first sidewall spacer concurrently with forming the gate contact hole;
performing a second RIE to remove the first sidewall spacer and first portion of the dielectric layer to expose the metal, further enlarging the source/drain contact hole; and
filling the further enlarged source/drain contact hole and gate contact hole with a contact metal.

15. The method according to claim 14, wherein the dielectric layer comprises a high-K (HK) dielectric.

16. The method according to claim 14, wherein the metal of the RMG includes at least one work function metal directly on the first portion of the dielectric layer and tungsten filling a remainder of the RMG, and the second RIE exposes the at least one work function metal.

17. The method according to claim 14, wherein the metal of the RMG includes at least one work function metal directly on each of the first and second portions of the dielectric layer and tungsten filling a remainder of the RMG, the method further comprising removing the at least one work function metal on the first portion of the dielectric layer concurrently with the first sidewall spacer and the first portion of the dielectric layer.

18. The method according to claim 17, further comprising:
forming the gate contact hole extending over the insulator surrounding the second sidewall spacer;
removing the insulator under the gate contact hole and surrounding the second sidewall spacer concurrently with forming the gate contact hole and
removing the second sidewall spacer, the second portion of the dielectric layer, and the at least one work function metal on the second portion of the dielectric layer concurrently with the first sidewall spacer and the first portion of the dielectric layer.

19. The method according to claim 14, comprising forming the source/drain contact down to a source/drain region, and forming a silicide on the source/drain region prior to filling the enlarged source/drain contact hole.

20. The method according to claim 14, wherein the contact metal comprises tungsten.
